(19) United States
(12) Patent Application Publication
(10) Pub. No.: US 2012/0326011 A1
(43) Pub. Date: Dec. 27, 2012

(54) IMAGE PICKUP DEVICE, ELECTRONIC APPARATUS, MANUFACTURING METHOD, AND INSPECTION APPARATUS

(75) Inventor: Isao Ichimura, Tokyo (JP)

(73) Assignee: SONY CORPORATION, Tokyo (JP)

(21) Appl. No.: 13/524,970

(22) Filed: Jun. 15, 2012

(30) Foreign Application Priority Data
Jun. 22, 2011 (JP) 2011-137983

(51) Int. Cl. H01L 31/0232; H01L 27/146; H01L 31/18

(52) U.S. Cl. 250/208.1; 257/432; 438/72; 257/E31.127

(57) ABSTRACT

An image pickup device includes a plurality of photodiodes, a photoelectric conversion part, and structures. The photoelectric conversion part is configured to convert light incident on the plurality of photodiodes into an electric signal. The structures each have a plano-convex shape and are formed to cover the plurality of photodiodes, the structures each having a concave part at a center of the plano-convex shape, and regions other than the concave part on each surface of the structures, the regions being covered by a light reflecting material.

### CROSS REFERENCES TO RELATED APPLICATIONS

The present application claims priority to Japanese Priority Patent Application JP 2011-137983 filed in the Japan Patent Office on Jun. 22, 2011, the entire content of which is hereby incorporated by reference.

### BACKGROUND

The present disclosure relates to an image pickup device, an electronic apparatus, a manufacturing method, and an inspection apparatus, and in particular, to an image pickup device, an electronic apparatus, a manufacturing method, and an inspection apparatus that improve detection sensitivity and achieve cost reduction.

In recent years, there has been an increased demand for chemical sensors or biosensors that display, as two-dimensional images, the measurement of the pH of solutions, the analysis of DNA and protein, or the like. Examples of such chemical sensors include a light-addressable potentiometric sensor (LAPS) that uses, for example, a surface photo voltage (SPV) method by which the surface potential of a semiconductor device is read from an excitation current resulting from a condensed light spot.

Such chemical sensors are allowed to capture a detection image as a two-dimensional map but need a transparent substrate or a transparent electrode to cause light to be incident on the surface of the substrate. In addition, these sensors have a single light source and a single device. Therefore, even if the light source is in the form of a spot, a generated excitation carrier is diffused in the plane direction of the semiconductor device, which results in the expansion of the range of an excitation current as an object to be observed. For this reason, such sensors have low image resolution.

Accordingly, there have been proposed many chemical sensors and biosensors that use, as detectors, solid-state image pickup devices such as CCD image sensors and CMOS image sensors serving as devices that have high detection sensitivity, produce a low-noise signal, and are capable of outputting a charge signal as two-dimensional data (see, for example, Japanese Patent Application Laid-open No. 2006-30162).

### SUMMARY

However, the above sensors are expected to have high precision to bring samples into alignment with photodiodes. As opposed to this, some sensors include a block that brings wells into alignment with detectors. In the case of such sensors, however, there is a difficulty in downsizing and simplifying an apparatus.

Further, some sensors directly mount samples as objects to be measured on their protection films or anti-reflection films to observe the samples. However, such sensors are not suited to the measurement of samples having low viscosity and also have a difficulty in measuring a plurality of types of samples at the same time.

Moreover, some sensors confine samples in wells formed on photodiodes. In the case of such sensors, however, metal well structures are expected to be provided on semiconductor devices, which results in a difficulty in cost reduction.

The present disclosure has been made in view of the above circumstances, and there is a need for an improvement in detection sensitivity and achievement in cost reduction.

According to a first embodiment of the present disclosure, there is provided an image pickup device including: a plurality of photodiodes; a photoelectric conversion part configured to convert light incident on the plurality of photodiodes into an electric signal; and structures that each have a plano-convex shape and are formed to cover the plurality of photodiodes, the structures each having a concave part at a center of the plano-convex shape, and regions other than the concave part on each surface of the structures, the regions being covered by a light reflecting material.

The structures may be formed of a light transmitting material.

The image pickup device may further include a layer between the structures and the photoelectric conversion part, the layer being formed of a photo-functional material configured to perform one of absorption and transmission of light in a specific wavelength range.

The structures may be formed of a photo-functional material configured to perform one of absorption and transmission of light in a specific wavelength range.

The structures may be formed for one of every single pixel and every plurality of pixels of the plurality of photodiodes.

According to a second embodiment of the present disclosure, there is provided an electronic apparatus including an image pickup device, the image pickup device including a plurality of photodiodes, a photoelectric conversion part configured to convert light incident on the plurality of photodiodes into an electric signal, and structures that each have a plano-convex shape and are formed to cover the plurality of photodiodes, the structures each having a concave part at a center of the plano-convex shape, and regions other than the concave part on each surface of the structures, the regions being covered by a light reflecting material.

According to a third embodiment of the present disclosure, there is provided a manufacturing method for an image pickup device, the manufacturing method including: forming an organic polymeric material layer on a wafer having photodiodes and a photoelectric conversion part formed thereon; forming resist patterns at predetermined positions in a region right above the photoelectric conversion part on the organic polymeric material layer, the resist patterns being configured to shield regions other than a center at each of the predetermined positions from light; performing a reflow process on the resist patterns to form structures each having a plano-convex shape, the structures being formed to cover the photodiodes and each having a concave part at a center of the plano-convex shape; and applying a light reflecting material to regions other than the concave part on each surface of the structures.

According to a fourth embodiment of the present disclosure, there is provided an inspection apparatus including an image pickup device, a light source, and a control unit. The image pickup device includes a plurality of photodiodes, a photoelectric conversion part configured to convert light incident on the plurality of photodiodes into an electric signal, and structures that each have a plano-convex shape and are formed to cover the plurality of photodiodes, the structures each having a concave part at a center of the plano-convex shape, and regions other than the concave part on each surface of the structures, the regions being covered by a light reflecting material. The light source is configured to irradiate a sample filled in the concave part with light. The control unit is configured to control the light source and the image pickup device.

In the first embodiment of the present disclosure, the image pickup device includes the plurality of photodiodes, the photoelectric conversion part configured to convert light incident on the photodiodes into an electric signal, and the structures that each have the plano-convex shape and are formed to cover the photodiodes. The structures each have the concave part at the center of the plano-convex shape, and the regions other than the concave part on each surface of the structures are covered by the light reflecting material.

In the second embodiment of the present disclosure, the electronic apparatus includes the image pickup device including the plurality of photodiodes, the photoelectric conversion part configured to convert light incident on the photodiodes into an electric signal, and the structures that each have the plano-convex shape and are formed to cover the photodiodes. The structures each have the concave part at the center of the plano-convex shape, and the regions other than the concave part on each surface of the structures are covered by the light reflecting material.

In the third embodiment of the present disclosure, the manufacturing method includes forming an organic polymeric material layer on a wafer having photodiodes and a photoelectric conversion part formed thereon, and forming resist patterns at predetermined positions in a region right above the photoelectric conversion part on the organic polymeric material layer, the resist patterns being configured to shield regions other than a center at each of the predetermined positions from light. A reflow process is performed on the resist patterns to form structures each having a plano-convex shape, the structures being formed to cover the photodiodes and each having a concave part at a center of the plano-convex shape. A light reflecting material is applied to regions other than the concave part on each surface of the structures.

In the fourth embodiment of the present disclosure, the inspection apparatus includes the image pickup device including the plurality of photodiodes, the photoelectric conversion part configured to convert light incident on the plurality of photodiodes into an electric signal, and the structures that each have the plano-convex shape and are formed to cover the plurality of photodiodes, the structures each having a concave part at a center of the plano-convex shape, and regions other than the concave part on each surface of the structures, the regions being covered by a light reflecting material. A sample filled in the concave part of the image pickup device is irradiated with light. Then, the light incident on the photodiodes is converted into an electric signal via the structures.

According to the first and second embodiments of the present disclosure, it is possible to obtain an electric signal converted from incident light. In particular, it is possible to improve detection sensitivity.

According to the third embodiment of the present disclosure, it is possible to manufacture an image pickup device. In particular, it is possible to manufacture an image pickup device having improved sensitivity at low cost.

According to the fourth embodiment of the present disclosure, it is possible to obtain an electric signal converted from incident light. In particular, it is possible to improve detection sensitivity.

These and other objects, features and advantages of the present disclosure will become more apparent in light of the following detailed description of best mode embodiments thereof, as illustrated in the accompanying drawings.

Additional features and advantages are described herein, and will be apparent from the following Detailed Description and the figures.

### BRIEF DESCRIPTION OF THE FIGURES

FIG. 1 is a cross-sectional view showing a configuration example of an image pickup device;

FIG. 2 is a flowchart for explaining a manufacturing process of the image pickup device;

FIG. 3 is a view for explaining the manufacturing process of the image pickup device;

FIG. 4 is a top view as seen from the top of a wafer in the manufacturing process;

FIG. 5 is a view for explaining an on-chip lens manufacturing process in the related art;

FIG. 6 is another view for explaining the on-chip lens manufacturing process in the related art;

FIG. 7 is another view for explaining the manufacturing process of the image pickup device;

FIG. 8 is a top view as seen from the top of the wafer in the manufacturing process;

FIG. 9 is a cross-sectional view showing another configuration example of an image pickup device; and

FIG. 10 is a diagram showing a configuration example of an inspection apparatus.

### DETAILED DESCRIPTION

Hereinafter, embodiments for carrying out the present disclosure (referred to as embodiments below) will be described with reference to the drawings. Note that the description will be given in the following order.
(1) First Embodiment (Image Pickup Device)
(2) Second Embodiment (Inspection Apparatus)

### (1) First Embodiment

(Configuration Example of Image Pickup Device)

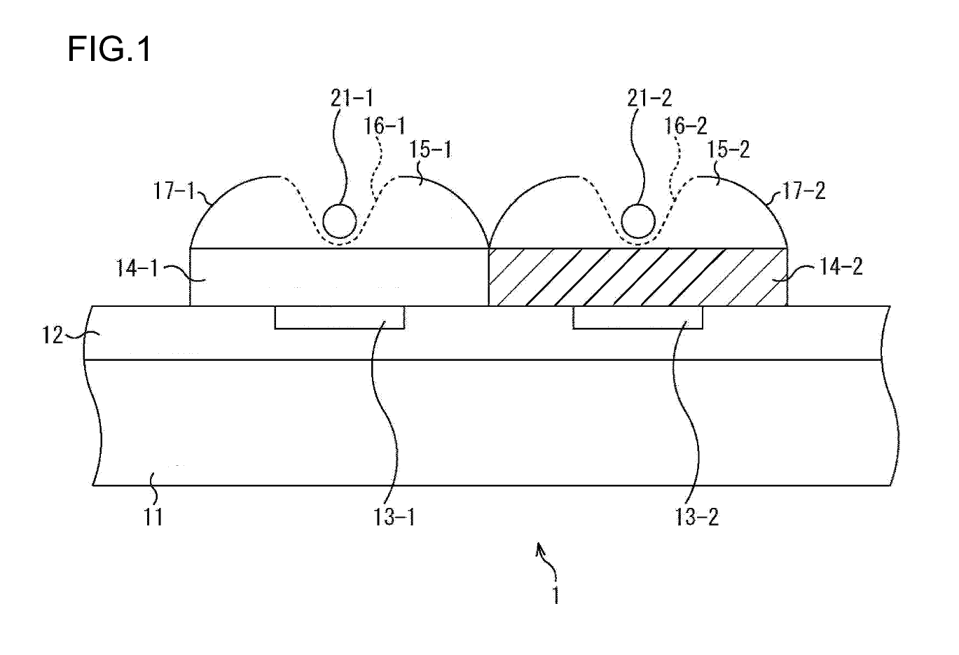

FIG. 1 is a cross-sectional view schematically showing the configuration of an embodiment of an image sensor serving as an image pickup device to which the present disclosure is applied.

The image sensor 1 shown in FIG. 1 is composed of an n-type substrate 11, a photoelectric conversion part 12 having photodiodes (PDs) 13-1 and 13-2, color filters 14-1 and 14-2, structures 15-1 and 15-2, and the like.

In the image sensor 1, the color filters 14-1 and 14-2 having wavelength selectivity are formed on the photodiodes 13-1 and 13-2 of the photoelectric conversion part 12, respectively. Further, the structures 15-1 and 15-2 having a plano-convex shape (lens shape) (also referred to as “plano-convex structure” below for the sake of convenience), which have concave parts (recesses) 16-1 and 16-2 at their centers, are formed on the color filters 14-1 and 14-2, respectively. Moreover, thin films 17-1 and 17-2 having light reflectivity are formed on the uppermost surfaces other than the concave parts 16-1 and 16-2 of the structures 15-1 and 15-2, respectively. Furthermore, as indicated by circles in FIG. 1, samples 21-1 and 21-2 in gel or liquid form as objects to be measured are accumulated in the concave parts 16-1 and 16-2 of the structures 15-1 and 15-2, respectively. The circles conceptualize the accumulation of the samples.

Note that the photodiodes 13-1 and 13-2, the color filters 14-1 and 14-2, and the structures 15-1 and 15-2 are referred to as photodiodes 13, color filters 14, and structures 15, respectively, below if there is no particular need to distinguish them. In addition, the concave parts 16-1 and 16-2, the thin films 17-1 and 17-2, and the samples 21-1 and 21-2 are referred to as concave parts 16, thin films 17, and samples 21, respectively, below if there is no particular need to distinguish them.

Further, in the example of FIG. 1, only the two photodiodes 13-1 and 13-2 are shown, but the photoelectric conversion part 12 actually has the plurality of photodiodes 13 arranged in matrix form on the n-type substrate 11.

The n-type substrate 11 is composed of a semiconductor wafer or the like. The photoelectric conversion part 12 is composed of, for example, solid-state image pickup devices such as CCDs (Charge Coupled Devices) and CMOSs (Complementary Metal Oxide Semiconductors). The photoelectric conversion part 12 detects the light phenomenon of the samples 21 and outputs the result of the detection as an electric signal.

The color filters 14 are formed on the photodiodes 13 to cover the same and have wavelength selectivity with their materials and mechanisms that transmit light in a specific wavelength range and absorb or reflect light in other wavelength ranges. In order to provide the color filters 14 with wavelength selectivity, some methods are available in the same manner as typical CCD image sensors and CMOS image sensors. More specifically, the known methods include a method of adding a polymeric material having a uniform thickness and a method of forming a multilayer film formed of an inorganic material to constitute an interference filter.

In the example of FIG. 1, the hatching of the color filter 14-2 indicates that the color filter 14-2 has wavelength selectivity different from that of the color filter 14-1. Like this, the color filters 14 may have different wavelength selectivity for every pixel (photodiode 13) depending on the intended use, but the configuration of the color filters 14 is not limited to this. For example, the color filters 14 may be composed of uniform filters having the same wavelength selectivity.

Note that the color filters 14 are provided to prevent the excitation light of a wavelength, which causes the light phenomenon to occur in the samples 21, from reaching the photodiodes 13 and the photoelectric conversion part 12. Accordingly, for example, if the light phenomenon occurs without the application of excitation light as in the case where the structures 15 have wavelength selectivity, it is possible to eliminate the color filters 14.

The plano-convex structures 15 having the concave part 16 at their centers are formed of a light transmitting material. The structures 15 are formed on the upper parts of the color filters 14, i.e., at predetermined positions in a region right above the photoelectric conversion part 12 to cover the photodiodes 13. The structures 15 are formed to separate neighboring pixels one from another and accumulate the samples 21 in the concave parts 16 to measure the light phenomenon. The concave parts 16 prevent the samples 21 from leaking out or mixing with the neighboring samples 21 even if the samples 21 are in gel or liquid form. Note that the samples 21 may be in any form other than a gel and liquid.

Here, the light phenomenon is observed in every direction. Therefore, in order to detect light emitted in a direction opposite to the photodiodes 13, there is a need for a mechanism for reflecting the light in the direction of the photodiodes 13.

To this end, the thin films 17 having light reflectivity and formed of a material such as AL, Au, Pt, or Cr are formed on the upper surfaces other than the regions of the concave parts 16 of the structures 15. Thus, the photodiodes 13 are allowed to capture the light phenomenon occurring in the structures 15 to a greater extent and detect a signal with high sensitivity.

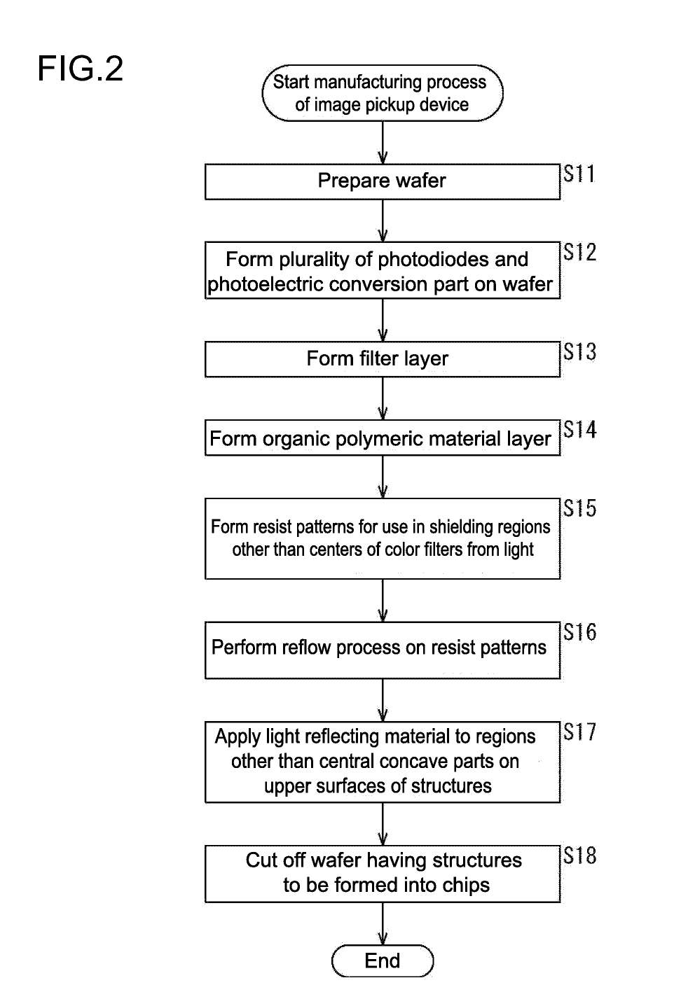

As described above, in the image sensor 1, the photodiodes 13 and the photoelectric conversion part 12 are integrally formed with the structures 15, which results in the elimination of an alignment process. Further, as will be described below with reference to FIG. 2, the structures 15 may be formed in a wafer process. Therefore, it is possible to perform alignment with submicron precision.

Note that in the example of FIG. 1, the color filters 14 are provided between the photoelectric conversion part 12 and the structures 15. However, without the provision of the color filters 14, the structures 15 themselves may be formed of a material having wavelength selectivity. For example, the structures 15 may have wavelength selectivity with their materials and mechanisms that transmit light in a specific wavelength range and absorb or reflect light in other wavelength ranges.

Next, a manufacturing method for the image sensor 1 shown in FIG. 1 will be described with reference to the flowchart of FIG. 2.

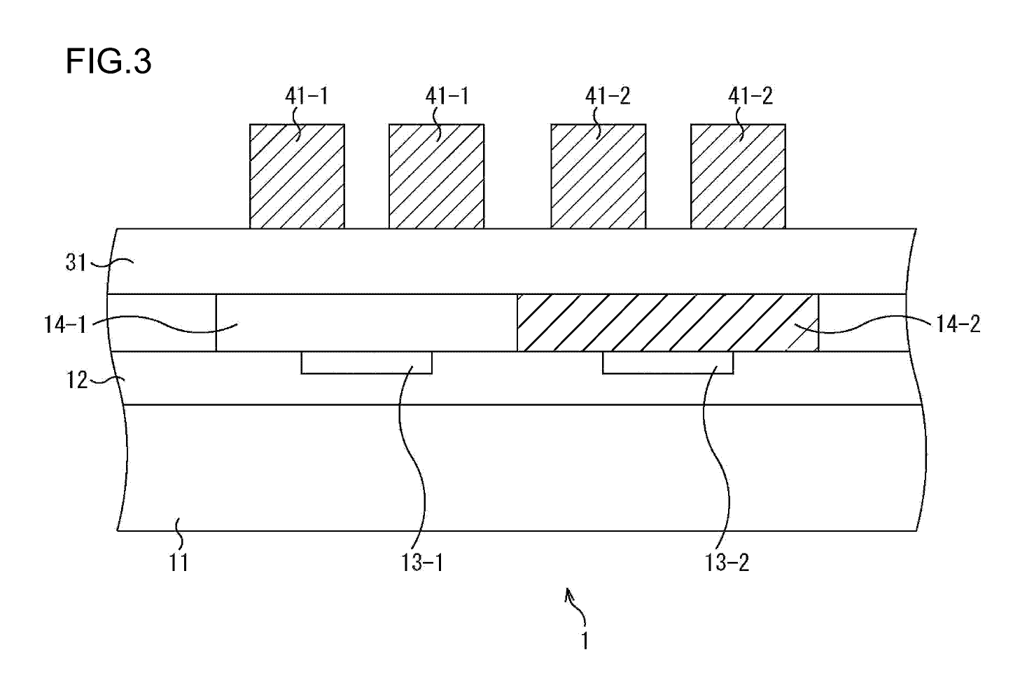

In step S11, an apparatus for manufacturing the image sensor 1 (referred to as the manufacturing apparatus below) prepares the n-type substrate 11 serving as a semiconductor wafer. In step S12, as shown in FIG. 3, the manufacturing apparatus forms, on the n-type substrate 11, the plurality of photodiodes 13 in matrix form and the photoelectric conversion part 12.

In step S13, the manufacturing apparatus forms, in the region right above the photodiodes 13 and the photoelectric conversion part 12, the filter layer of the color filters 14 formed of a wavelength selecting material to cover the photodiodes 13.

Note that the above processes in steps S11 to S13 are not particularly limited. That is, it is possible to use known manufacturing methods for photoelectric conversion devices or the like.

In step S14, an organic polymeric material layer 31 is formed on the filter layer. The organic polymeric material layer 31 is formed into the structures 15 later.

In step S15, as shown in FIG. 3, the manufacturing apparatus forms resist patterns 41 for use in shielding regions other than the centers of the color filters 14 from light, i.e., for use in exposing the centers of the color filters 14 in the organic polymeric material layer 31. The resist patterns 41 are formed at predetermined positions in the region right above the photoelectric conversion part 12 so that the structures 15 each having the concave part 16 are formed to cover the photodiodes 13.

More specifically, the manufacturing apparatus forms, on the organic polymeric material layer 31, a photosensitive resist layer to shield regions other than the center of the color filter 14-1 from light. Then, the manufacturing apparatus exposes regions other than a part serving as the plano-convex structure of the resist layer to harden a resist resin. The regions other than hardened region are removed after being subjected to development processing. The region obtained by inverting an exposure mask is transferred and formed as a resist pattern 41-1. Similarly, as for the color filter 14-2, a resist pattern 41-2 for use in shielding regions other than the center of the color filter 14-2 from light is formed.

Note that the resist patterns 41-1 and 41-2 are referred to as resist patterns 41 below if there is no particular need to distinguish them.

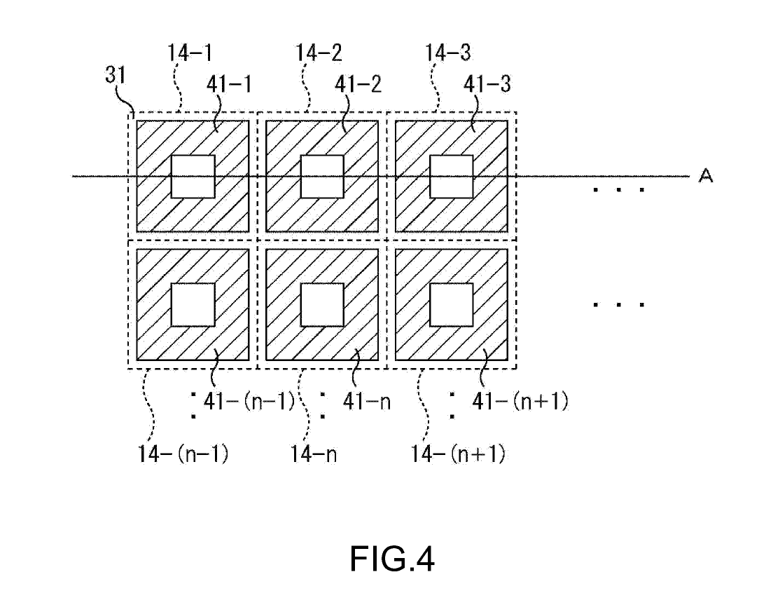

FIG. 4 is a top view as seen from the top of the image sensor 1 in which the resist patterns 41 are formed. The cross-sectional view taken along the line A in the example of FIG. 4 corresponds to FIG. 3. Note that in the example of FIG. 4, the color filters 14 are represented by dotted lines because they are arranged below the organic polymeric material layer 31.

The resist pattern 41-1 is formed to shield the regions other than the center of the color filter 14-1 from light. The resist pattern 41-2 is formed to shield the regions other than the center of the color filter 14-2 from light. A resist pattern 41-3 is formed to shield regions other than the center of a color filter 14-3 from light. A resist pattern 41-(n−1) is formed to shield regions other than the center of a color filter 14-(n−1) from light. A resist pattern 41-n is formed to shield regions other than the center of a color filter 14-n from light. A resist pattern 41-(n+1) is formed to shield regions other than the center of a color filter 14-(n+1) from light.

Note that in the example of FIG. 4, only the six color filters 14 and the six resist patterns 41 are shown, but the image sensor 1 actually has the plurality of color filters 14 and resist patterns 41.

Further, in the examples of FIGS. 3 and 4, the centers of the resist patterns 41 are in the form of a square, but the shape of the centers of the resist patterns 41 is not particularly limited. Moreover, in the examples of FIGS. 3 and 4, the resist patterns 41 are formed at the regions other than the centers of the color filters 41 and other than the boundaries between the color filters 14. This aims to prevent the organic polymeric material layer 31 from overflowing in the next step.

Referring back to FIG. 2, in step S16, the manufacturing apparatus performs a reflow process on the resist patterns 41. More specifically, in order to perform the reflow process, the manufacturing apparatus applies, to the resist patterns 41, temperature in the range in which the color filters 14 are not thermally faded. As the reflow process, it is possible to use a method of applying a dry etching process using a mixed gas to etch back the entire organic polymeric material layer 31 in the same manner as an on-chip lens manufacturing method described in, for example, Japanese Patent No. 3355874.

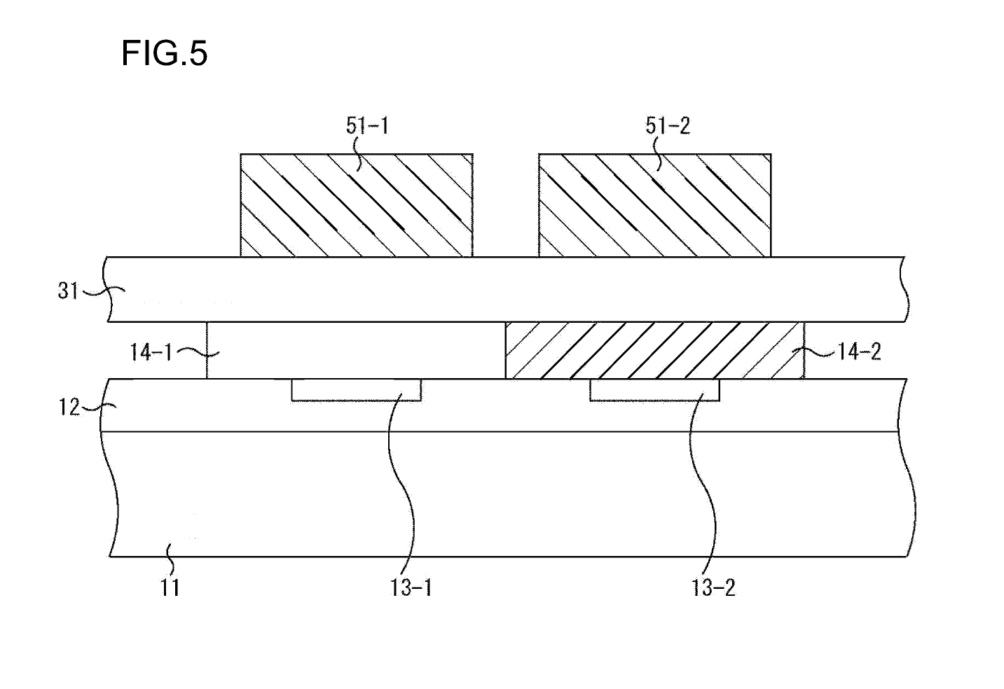

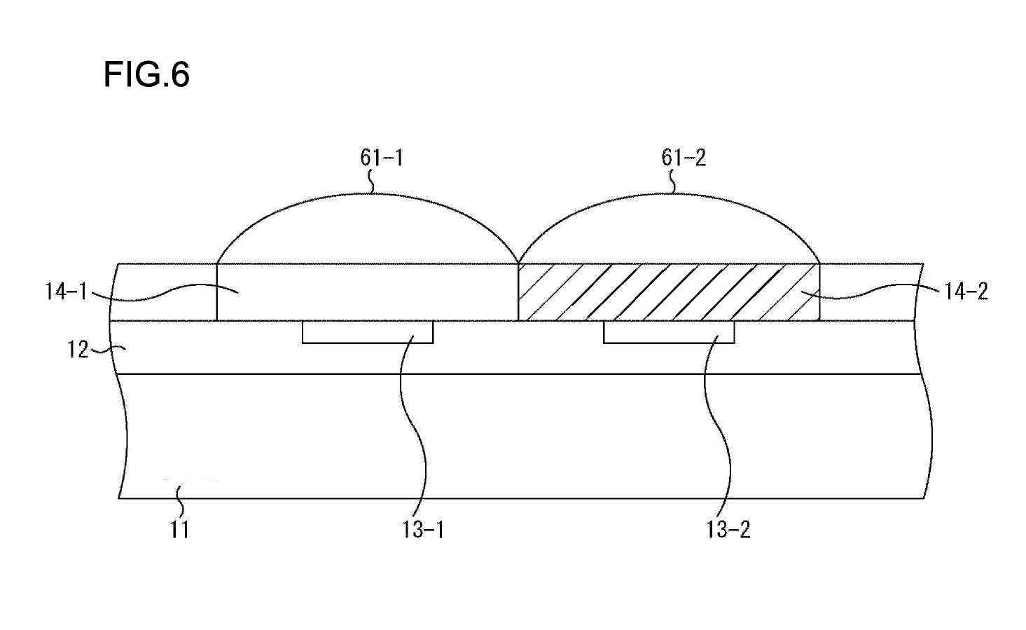

FIGS. 5 and 6 are views for explaining an on-chip lens manufacturing method in the related art for comparison with a method of forming the structures 15.

As shown in FIG. 5, with the on-chip lens manufacturing method in the related art, a resist pattern 51-1 on the organic polymeric material layer 31 is formed on the color filter 14-1 to be slightly smaller than the color filter 14-1. Similarly, a resist pattern 51-2 is formed on the color filter 14-2 to be slightly smaller than the color filter 14-2.

Accordingly, with the above method of applying a dry etching process using a mixed gas to etch back the entire organic polymeric material layer 31, high quality plano-convex on-chip lenses 61-1 and 61-2 suited to condensing are formed as shown in FIG. 6.

On the other hand, in the image sensor 1, the resist patterns 41 are formed to shield the regions other than the centers of the color filters 14 from light, i.e., formed to expose the centers of the color filters 14.

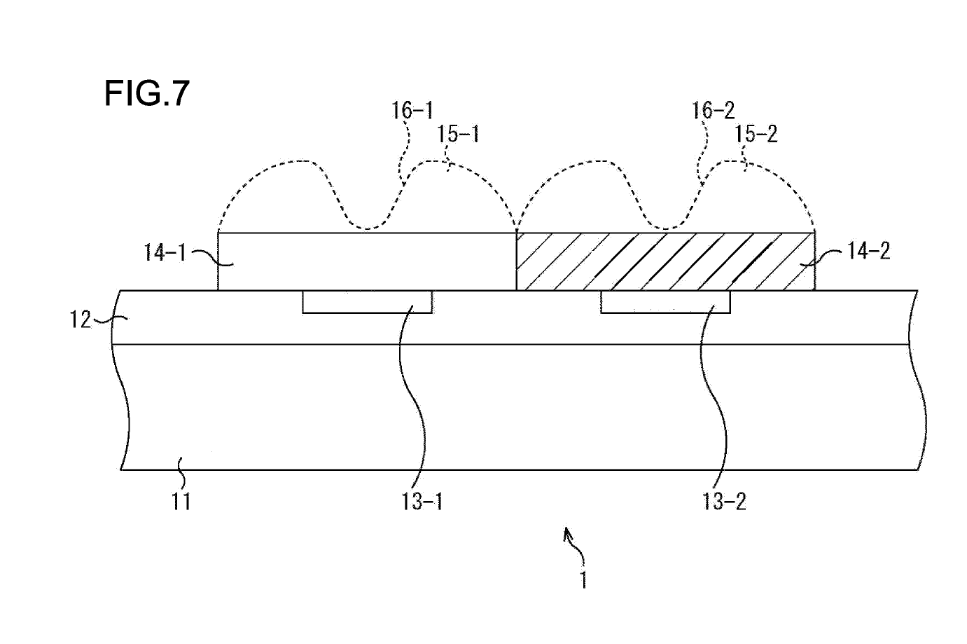

Accordingly, with the reflow process, the plano-convex structures 15 each having the concave part 16 are formed on the color filters 14, i.e., at the predetermined positions in the region right above the photoelectric conversion part 12 to cover the photodiodes 13 as shown in FIG. 7. In the example of FIG. 7, the plano-convex structure 15-1 having the concave part 16-1 is formed on the color filter 14-1, and the plano-convex structure 15-2 having the concave part 16-2 is formed on the color filter 14-2.

Thus, with the reflow process, the plano-convex structures 15 having a curvature providing a higher condensing ratio are formed.

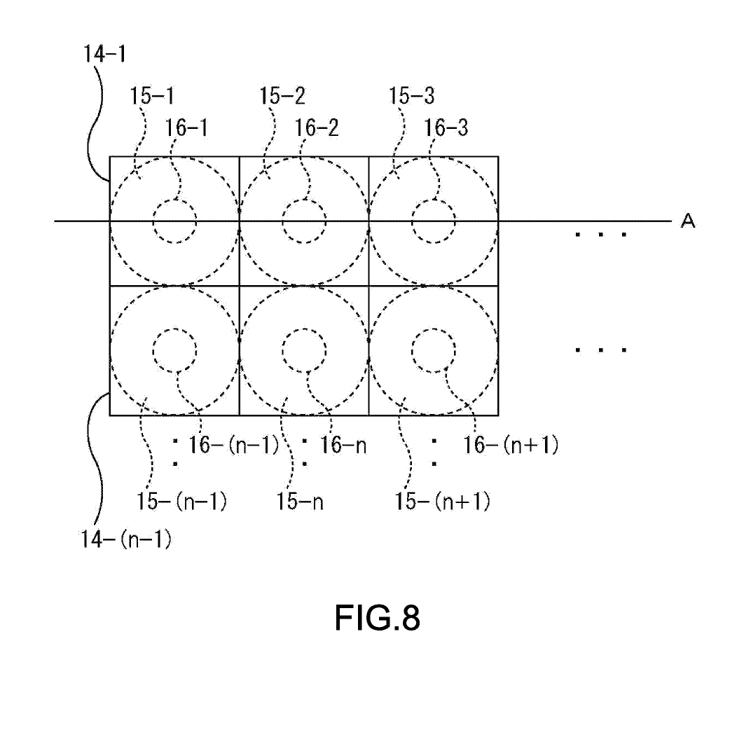

FIG. 8 is a top view as seen from the top of the image sensor 1 in which the plano-convex structures 15 each having the concave part 16 are formed. The cross-sectional view taken along the line A in the example of FIG. 8 corresponds to FIG. 7.

The plano-convex structure 15-1 having the concave part 16-1 is formed on the color filter 14-1. The plano-convex structure 15-2 having the concave part 16-2 is formed on the color filter 14-2. A plano-convex structure 15-3 having a concave part 16-3 is formed on the color filter 14-3. A plano-convex structure 15-(n−1) having a concave part 16-(n−1) is formed on the color filter 14-(n−1). A plano-convex structure 15-n having a concave part 16-n is formed on the color filter 14-n. A plano-convex structure 15-(n+1) having a concave part 16-(n+1) is formed on the color filter 14-(n+1).

Note that in the example of FIG. 8, only the six color filters 14 and the six structures 15 are shown, but the image sensor 1 actually has the plurality of color filters 14 and structures 15.

Further, in the examples of FIGS. 7 and 8, the structures 15 do not cover the four corners of the color filters 14 because of their schematic representations, but they are actually formed to cover the four corners according to the reflow process on the organic polymeric material layer 31.

Moreover, in the example of FIG. 8, the concave parts 16 are indicated by perfect circles, but the shape of the concave parts 16 may be an ellipse without being limited to a circle. That is, the concave parts 16 may have any shape.

Referring back to FIG. 2, in step S17, the manufacturing apparatus applies a light reflecting material to the regions other than the central concave parts 16 on the upper surfaces of the structures 15.

The manufacturing apparatus applies the light reflecting material to the regions other than the central concave parts 16 on the upper surfaces of the structures 15 according to a deposition process, a coating process, or the like, to form the thin films 17 having light reflectivity. As the light reflecting material, a metal material such as AL, Au, Pt, or Cr is, for example, used.

Thus, the manufacturing apparatus reflects the light, which is dissipated in an upper direction as the light phenomenon occurring in the structures 15, in the direction of the photodiodes 13 and captures the reflected light in the image sensor 1. As a result, the manufacturing apparatus is allowed to detect a signal with high sensitivity.

Referring back to FIG. 2 again, in step S18, the manufacturing apparatus cuts off the wafer having the structures 15 to be formed into chips.

As described above, the image sensor 1 is manufactured by the application of the technology of manufacturing semiconductor chips or the like. Therefore, the plano-convex structures 15 may be formed at the predetermined positions in the region right above the photoelectric conversion part 12 (i.e., at the positions at which the photodiodes 13 are covered) with high precision.

In addition, the photodiodes 13, the photoelectric conversion part 12, and the structures 15 each having the concave part 16 are integrally formed with each other, which results in the elimination of an alignment section. Thus, with the downsizing and simplification of the apparatus, it is possible to achieve cost reduction.

(Configuration Example of Image Pickup Device)

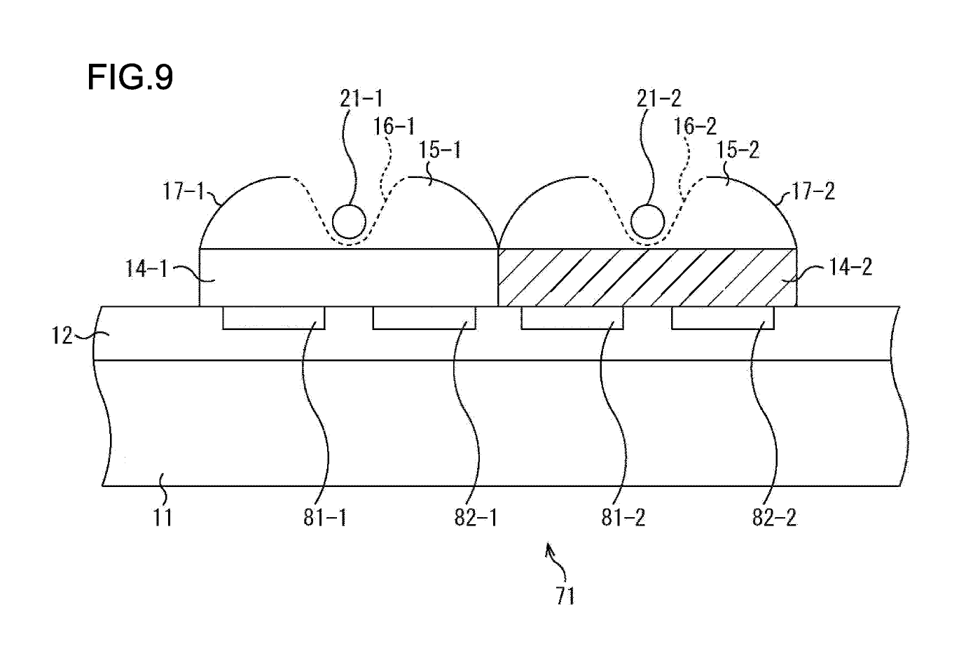

FIG. 9 is a cross-sectional view schematically showing the configuration of another embodiment of an image sensor serving as an image pickup device to which the present disclosure is applied.

The image sensor 71 shown in FIG. 9 is composed of the n-type substrate 11, the photoelectric conversion part 12 having photodiodes 81-1 to 84-1 and photodiodes 81-2 to 84-2, the color filters 14-1 and 14-2, the structures 15-1 and 15-2, and the like.

Note that the photodiodes 83-1 and 84-1 and the photodiodes 83-2 and 84-2 are not shown in FIG. 9 because FIG. 9 is a cross-sectional view. However, in the example of FIG. 9, the single structure is actually formed relative to the four photodiodes.

In other words, in the image sensor 1 shown in FIG. 1, the single structure is formed relative to the single photodiode. On the other hand, in the image sensor 71, the color filter 14-1 having wavelength selectivity is formed on the plurality of photodiodes 81-1 to 84-1, and the single structure 15-1 is formed relative to the plurality of pixels. Further, the color filter 14-2 having wavelength selectivity is formed on the plurality of photodiodes 81-2 to 84-2, and the single structure 15-2 is formed relative to the plurality of pixels.

Further, as in the case of the image sensor 1 shown in FIG. 1, the plano-convex structures 15-1 and 15-2 having concave parts (recesses) 16-1 and 16-2 at their centers are formed on the color filters 14-1 and 14-2, respectively. Moreover, the thin films 17-1 and 17-2 having light reflectivity are formed on the uppermost surfaces other than the concave parts 16-1 and 16-2 of the structures 15-1 and 15-2, respectively. Furthermore, as indicated by the circles in FIG. 8, the samples 21-1 and 21-2 in gel or liquid form as objects to be measured are accumulated in the concave parts 16-1 and 16-2 of the structures 15-1 and 15-2, respectively.

Note that the photodiodes 81-1 to 84-1 and the photodiodes 81-2 to 84-2 are referred to as photodiodes 81 to 84 below if there is no particular need to distinguish them.

Further, in the example of FIG. 9, the single structure 15 is formed relative to the photodiodes 81 to 84, but the number of photodiodes is not limited to four. That is, the image sensor 71 may have six or more photodiodes.

As described above, the plurality of pixels (photodiodes 81-1 to 84-1) are formed relative to the single sample 21-1 to detect the light phenomenon, which makes it possible to increase a signal-to-noise (S/N) ratio. Further, as for the neighboring sample 21-2, the corresponding plurality of pixels (photodiodes 81-2 to 84-2) and the color filter 14-2 similarly detect the light phenomenon. Thus, although its detection density is reduced if the number of pixels is the same, the image sensor 71 is allowed to detect a signal with higher sensitivity than the image sensor 1 shown in FIG. 1.

Further, in the image sensor 71, the photodiodes 81 to 84 and the photoelectric conversion part 12 are integrally formed with the structures 15 each having the concave part 16, which results in the elimination of an alignment process and an alignment section. Moreover, although its diagrammatic representation and description are omitted here, the image sensor 71 may be manufactured in the same manner as the manufacturing method for the image sensor 1 described above with reference to FIG. 2. Therefore, it is possible to perform alignment with submicron precision.

As described above, according to the present disclosure, the photodiodes and the photoelectric conversion part are integrally formed with the structures having each the concave part, which makes it possible to downsize and simplify the apparatus and manufacture the apparatus at low cost.

In addition, according to the present disclosure, the thin films having light reflectivity are applied to the outermost surfaces other than the concave parts of the plano-convex structures formed on the photodiodes. Therefore, the light emitted in the upper direction (opposite to the photodiodes) from the samples is reflected and introduced into the side of the photodiodes, which results in an increase in the detection sensitivity of a signal.

Accordingly, with an increase in the detection sensitivity of a signal as described above, it is possible to reduce a detection error and reliably detect a chemical reaction with few samples.

### (2) Second Embodiment

(Configuration Example of Inspection Apparatus)

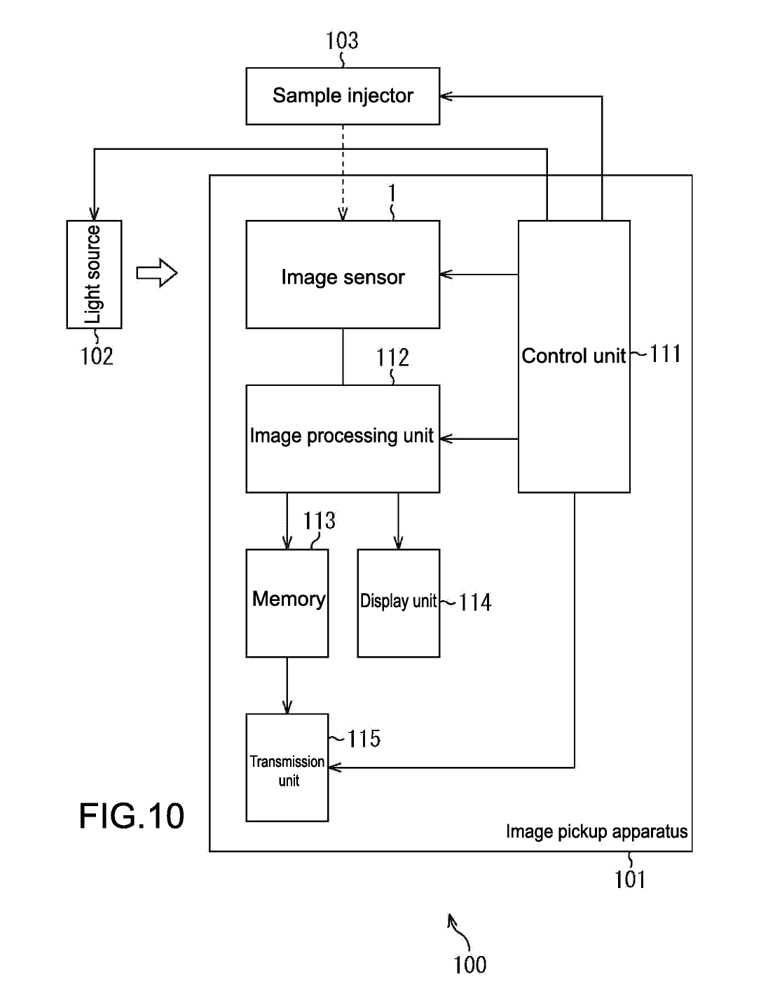

FIG. 10 is a diagram schematically showing the configuration of an embodiment of an inspection apparatus using the image sensor serving as an image pickup device to which the present disclosure is applied.

The inspection apparatus 100 shown in FIG. 10 is composed of an image pickup apparatus 101, a light source 102, and a sample injector 103. The image pickup apparatus 101 is composed of the image sensor 1 shown in FIG. 1, a control unit 111, an image processing unit 112, a memory 113, a display unit 114, and a transmission unit 115.

The photodiodes 13 and the photoelectric conversion part 12 of the image sensor 1 capture, under the control of the control unit 111, the light phenomenon occurring in the structures 15 having the sample accumulated in the concave part 16, and then output the captured light phenomenon to the image processing unit 112 as an electric signal.

The control unit 111 controls the respective units of the image pickup apparatus 101 and controls the light emission timing of the light source 102 to control the sample injection timing of the sample injector 103. For example, the control unit 111 controls the image pickup timing of the image sensor 1, the image processing of the image processing unit 112, and the transmission of the transmission unit 115.

The image processing unit 12 performs, under the control of the control unit 111, signal processing suited to an image corresponding to the electric signal from the image sensor 1, and stores the processed image and data in the memory 113 or display them on the display unit 114. For example, the image processing unit 112 processes the image corresponding to the electric signal from the image sensor 1 to output the data of a sequence or data indicating the reaction statuses of the image sensor 1.

The memory 113 stores the image and data processed by the image processing unit 112. The display unit 114 displays the image and data processed by the image processing unit 112. The transmission unit 115 transmits the image and data stored in the memory 113 to an apparatus (not shown) connected by, for example, a USB cable.

The light source 102 emits light according to the timing of the control unit 111. The sample injector 103 injects, under the control of the control unit 111, the samples as objects to be inspected into the concave parts 16 of the structures 15 of the image sensor 1.

The inspection apparatus 100 shown in FIG. 10 uses the image sensor 1 having the photodiodes 13 and the photoelectric conversion part 12 that are integrally formed with the structures 15 as described above, which results in the elimination of an alignment process and an alignment section. As a result, it is possible to achieve the downsizing and cost reduction of the apparatus.

Further, it is possible to perform alignment with submicron precision and perform an inspection with high precision.

Note that the embodiments of the present disclosure are not limited to the above, and various modifications may be made without departing from the gist of the present disclosure.

Thus, the embodiments of the present disclosure are described in detail above with reference to the accompanying drawings, but the present disclosure is not limited to such embodiments. It is clear that those having common knowledge in the technical field to which the present disclosure pertains may conceive various modified embodiments and corrected embodiments within the technical ideas described in the claims, and thus is understood that such modified embodiments and corrected embodiments are of course within the technical scope of the present disclosure.

Note that the present disclosure may employ the following configurations.

(1) An image pickup device, including:

a plurality of photodiodes;

a photoelectric conversion part configured to convert light incident on the plurality of photodiodes into an electric signal; and

structures that each have a plano-convex shape and are formed to cover the plurality of photodiodes, the structures each having a concave part at a center of the plano-convex shape, and regions other than the concave part on each surface of the structures, the regions being covered by a light reflecting material.

(2) The image pickup device according to (1), in which

the structures are formed of a light transmitting material.

(3) The image pickup device according to (1) or (2), further including a layer between the structures and the photoelectric conversion part, the layer being formed of a photo-functional material configured to perform one of absorption and transmission of light in a specific wavelength range.

(4) The image pickup device according to (1), in which

the structures are formed of a photo-functional material configured to perform one of absorb absorption and or transmit transmission of light in a specific wavelength range.

(5) The image pickup device according to (1) to (4), in which

the structures are formed for one of every single pixel and every plurality of pixels of the plurality of photodiodes.

(6) An electronic apparatus, including an image pickup device, the image pickup device including

a plurality of photodiodes,

a photoelectric conversion part configured to convert light incident on the plurality of photodiodes into an electric signal, and

structures that each have a plano-convex shape and are formed to cover the plurality of photodiodes, the structures each having a concave part at a center of the plano-convex shape, and regions other than the concave part on each surface of the structures, the regions being covered by a light reflecting material.

(7) A manufacturing method for an image pickup device, the manufacturing method including:

forming an organic polymeric material layer on a wafer having photodiodes and a photoelectric conversion part formed thereon;

forming resist patterns at predetermined positions in a region right above the photoelectric conversion part on the organic polymeric material layer, the resist patterns being configured to shield regions other than a center at each of the predetermined positions from light;

performing a reflow process on the resist patterns to form structures each having a plano-convex shape, the structures being formed to cover the photodiodes and each having a concave part at a center of the plano-convex shape; and

applying a light reflecting material to regions other than the concave part on each surface of the structures.

(8) An inspection apparatus, including:

an image pickup device including
a plurality of photodiodes,
a photoelectric conversion part configured to convert light incident on the plurality of photodiodes into an electric signal, and
structures that each have a plano-convex shape and are formed to cover the plurality of photodiodes, the structures each having a concave part at a center of the plano-convex shape, and regions other than the concave part on each surface of the structures, the regions being covered by a light reflecting material;;

a light source configured to irradiate a sample filled in the concave part with light; and

a control unit configured to control the light source and the image pickup device.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. An image pickup device, comprising:
a plurality of photodiodes;
a photoelectric conversion part configured to convert light incident on the plurality of photodiodes into an electric signal; and
structures that each have a plano-convex shape and are formed to cover the plurality of photodiodes, the structures each having a concave part at a center of the plano-convex shape, and regions other than the concave part on each surface of the structures, the regions being covered by a light reflecting material.

2. The image pickup device according to claim 1, wherein
the structures are formed of a light transmitting material.

3. The image pickup device according to claim 2, further comprising a layer between the structures and the photoelectric conversion part, the layer being formed of a photo-functional material configured to perform one of absorption and transmission of light in a specific wavelength range.

4. The image pickup device according to claim 1, wherein
the structures are formed of a photo-functional material configured to perform one of absorption and transmission of light in a specific wavelength range.

5. The image pickup device according to claim 1, wherein
the structures are formed for one of every single pixel and every plurality of pixels of the plurality of photodiodes.

6. An electronic apparatus, comprising an image pickup device, the image pickup device including
a plurality of photodiodes,
a photoelectric conversion part configured to convert light incident on the plurality of photodiodes into an electric signal, and
structures that each have a plano-convex shape and are formed to cover the plurality of photodiodes, the structures each having a concave part at a center of the plano-convex shape, and regions other than the concave part on each surface of the structures, the regions being covered by a light reflecting material.

7. A manufacturing method for an image pickup device, the manufacturing method comprising:
forming an organic polymeric material layer on a wafer having photodiodes and a photoelectric conversion part formed thereon;
forming resist patterns at predetermined positions in a region right above the photoelectric conversion part on the organic polymeric material layer, the resist patterns being configured to shield regions other than a center at each of the predetermined positions from light;
performing a reflow process on the resist patterns to form structures each having a plano-convex shape, the structures being formed to cover the photodiodes and each having a concave part at a center of the plano-convex shape; and
applying a light reflecting material to regions other than the concave part on each surface of the structures.

8. An inspection apparatus, comprising:
an image pickup device including
a plurality of photodiodes,
a photoelectric conversion part configured to convert light incident on the plurality of photodiodes into an electric signal, and
structures that each have a plano-convex shape and are formed to cover the plurality of photodiodes, the structures each having a concave part at a center of the plano-convex shape, and regions other than the concave part on each surface of the structures, the regions being covered by a light reflecting material;
a light source configured to irradiate a sample filled in the concave part with light; and
a control unit configured to control the light source and the image pickup device.
